(19) United States
(12) Patent Application Publication
(10) Pub. No.: US 2024/0142496 A1
(43) Pub. Date: May 2, 2024

(54) CONDUCTIVE PERFORATED PLATE FOR ELECTRICAL TEST

(71) Applicant: TEXAS INSTRUMENTS INCORPORATED, Dallas, TX (US)

(72) Inventors: Wolfgang Weiss, Landshut (DE); Anton Johann Bayerstadler, Ebersberg (DE); Peter Bakker, Muenchen (DE)

(21) Appl. No.: 17/975,071

(22) Filed: Oct. 27, 2022

(51) Int. Cl. G01R 1/073; H01L 21/66

(52) U.S. Cl. CPC G01R 1/07342; H01L 22/14; H01L 22/32

(57) ABSTRACT

The present disclosure generally relates to a conductive perforated plate for electrical testing of a device under test (DUT) in semiconductor processing. In an example, a device circuit in a die area is formed in or over a semiconductor substrate. The device circuit has an interconnect level. A DUT is formed in or over the semiconductor substrate. A conductive perforated plate is formed in the interconnect level conductively connected to the DUT. A plurality of insulating islands is disposed within the conductive perforated plate.

### BACKGROUND

Semiconductor processing to fabricate integrated circuit (IC) dies may include many processing steps. The costs to perform these processing steps to a completed IC die can be large. Commonly, one or more electrical tests may be performed on a substrate (e.g., wafer) that contains the IC dies at various stages of the processing steps. Performing tests at intermediate stages of processing can permit a manufacturer to identify IC dies on the substrate that are defective and can permit the manufacturer to more narrowly search for a source of defects. By identifying defective substrates earlier in processing, processing on defective substrates can be avoided. Further, being able to more narrowly search for defect sources can reduce engineering time and costs, as well as allow for earlier corrective action to be taken for processing subsequent substrates.

### SUMMARY

This Summary is provided to introduce a brief selection of disclosed concepts in a simplified form that are further described below in the Detailed Description including the drawings provided. Various disclosed devices and methods may be beneficially applied for fabricating an integrated circuit (IC) die. While such examples may be expected to reduce the occurrence of defects in IC dies, no particular result is a requirement unless explicitly recited in a particular claim.

An example described herein is a method of forming a semiconductor device. A device circuit in a die area is formed in or over a semiconductor substrate. The device circuit has an interconnect level. A device under test (DUT) is formed in or over the semiconductor substrate. A conductive perforated plate is formed in the interconnect level conductively connected to the DUT. A plurality of insulating islands is disposed within the conductive perforated plate.

Another example is a method of fabricating an integrated circuit. A perforated metal plate is contacted with a probe pin of a test probe. The perforated metal plate is conductively connected to a device under test formed on or over a semiconductor substrate and adjacent a die area of the semiconductor substrate. A plurality of insulating islands is disposed through the perforated metal plate. An electrical test of the device under test is performed with the probe pin in contact with the perforated metal plate. A die comprising the die area is packaged.

A further example is an integrated circuit. The integrated circuit includes a device circuit, a conductive plate, and a plurality of insulating islands. The device circuit is in a die area in or over a semiconductor substrate. The device circuit has an interconnect level including a dielectric material over the semiconductor substrate. The conductive plate is in the interconnect level. The plurality of insulating islands is within the conductive plate. The insulating islands include the dielectric material.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a partial layout view of a substrate on which integrated circuit (IC) dies are fabricated according to some examples.

FIG. 2 is a partial layout view of a substrate on which IC dies are fabricated according to some examples.

FIG. 3 is a partial layout view of a substrate on which IC dies are fabricated according to some examples.

FIG. 4 is a layout view of a device under test (DUT) area according to some examples.

FIG. 5 is a layout view of a metal probe pad in relation to an underlying conductive perforated plate according to some examples.

FIG. 6 is a partial cross-sectional view of the substrate of FIG. 1 according to some examples.

FIG. 7A is a layout view of a photomask for forming a conductive perforated plate, and FIG. 7B is a layout view of the resulting conductive perforated plate according to some examples.

FIG. 8A is a layout view of a photomask for forming a conductive perforated plate, and FIG. 8B is a layout view of the resulting conductive perforated plate according to some examples.

FIG. 9A is a layout view of a photomask for forming a conductive perforated plate, and FIG. 9B is a layout view of the resulting conductive perforated plate according to some examples.

FIG. 10A is a layout view of a photomask for forming a conductive perforated plate, and FIG. 10B is a layout view of the resulting conductive perforated plate according to some examples.

FIG. 11 is a partial cross-sectional view of the substrate of FIG. 1 during fabrication according to some examples.

FIG. 12 is a partial cross-sectional view of a substrate, in which a conductive perforated plate is disposed in and formed in a contact interconnect level, during fabrication according to some examples.

FIG. 13 is a partial cross-sectional view of a substrate, in which a conductive perforated plate is disposed in and formed in a fifth via interconnect level, during fabrication according to some examples.

FIG. 14 is a partial cross-sectional view of a substrate, in which a conductive perforated plate is disposed in and formed in a passivation via interconnect level, during fabrication according to some examples.

FIGS. 15A and 15B are a partial cross-sectional view and a partial layout view, respectively, of an IC die singulated from the substrate of FIG. 1 according to some examples.

FIG. 16 is a cross-sectional view of an IC package according to some examples.

FIG. 17 is a flow chart of a method of semiconductor processing according to some examples.

FIGS. 18 through 22 are cross-sectional views at various stages of the method of semiconductor processing of FIG. 17 that may form the example structures illustrated in FIG. 6 according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and may be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates to a conductive perforated plate in an interconnect level that may be used as a probe pad for electrical testing of a device under test (DUT) in semiconductor processing. In an electrical test, the conductive perforated plate can be contacted by a probe pin of a test probe. The conductive perforated plate may be more robust relative to baseline structures contacted by a probe pin during electrical testing. Such robustness can reduce occurrences of defects that occurred using the baseline structures.

Electrical testing may be performed by a probe pin contacting a probe pad in a metal level during semiconductor processing. A metal level generally includes metal lines, metal pads, or combinations thereof. Metal lines are generally configured to laterally distribute signals or power across an IC die area, and metal pads may generally be configured for contact by components external to an IC die (e.g., a wire bond or probe pin) and/or for contacting or landing one or more vias. “Metal line/pad” is used herein to generically refer to a metal line, a metal pad, or a combination thereof in a metal level. An interconnect level generally includes metal plugs (e.g., metal contacts to the substrate and/or metal vias between metal levels) that vertically (as opposed to laterally) connect an underlying component (whether a doped region in a semiconductor substrate or metal line/pad in a metal level) to an overlying metal line/pad in an overlying metal level or under-bump metal (UBM).

Manufacturing requirements for metal levels can result in a probe pad in a metal level being formed of a relatively soft material, such as aluminum or an aluminum alloy. When a probe pin is caused to contact the probe pad for electrical testing, the probe pin may contact the probe pad with a given overdrive. The overdrive may provide sufficient assurance that a low resistance contact between the probe pin and probe pad is formed that does not significantly affect parameters to be measured by the test. The overdrive of the probe pin can scratch or otherwise damage the probe pad, particularly due to the relatively soft material of the probe pad. A crown can be formed on the probe pad from the contact of the probe pin. The topology of this crown on the probe pad can result in a subsequently deposited insulating layer (e.g., a dielectric layer) not covering the crown (e.g., due to the original height of the crown being greater than the thickness of the insulating layer after planarizing the insulating layer, such as by a chemical mechanical polish (CMP)). The crown, and thereby, the probe pad, may therefore be exposed during subsequent processing. For example, during the CMP to planarize the insulating layer, hydrofluoric acid in the CMP slurry may etch the crown and probe pad resulting in an undesired cavity. This cavity can cause a spin defect where a photoresist in a photolithography process lacks sufficient adhesion. The spin defect then can cause subsequently deposited metal to be deposited in an area where the IC is designed to not have metal, which may cause a short circuit or other defect of the IC.

Examples described herein can avoid or mitigate against such defects. As detailed below, a conductive perforated plate in an interconnect level may have a stronger structure while having sufficient electrical characteristics for electrical testing. In some examples, a conductive material, such as a metal, of an interconnect level may be harder than aluminum or an aluminum alloy (such as aluminum copper (Al₁₋ₓCuₓ, where x≤0.02), aluminum silicon (AlSi), or the like). For example, an interconnect level may include tungsten on a barrier layer (e.g., titanium nitride, tantalum nitride, or the like). Tungsten has a greater hardness than aluminum. Tungsten is hard, has a strong tensile strength, has a low thermal expansion, has high thermal and electrical conductivity, and has a low reactivity with water, acids, and bases. Hence, tungsten is an example material to implement a conductive perforated plate, although other metals or conductive materials may be used.

A conductive perforated plate may follow applicable design and manufacturing rules (e.g., according to the technology node) for the respective interconnect level. The conductive perforated plate may have insulating islands of the insulating layer in which the conductive perforated plate is disposed. The insulating islands may permit the conductive perforated plate to follow design and manufacturing rules of the interconnect level regarding critical dimension and filling, for example. Among other things, a surface area ratio of the top surface of the conductive perforated plate to the top surfaces of the insulating islands within the conductive perforated plate may be sufficient to permit a low resistance contact between a probe pin and the conductive perforated plate.

In some examples, the harder metal (such as tungsten) used for the conductive perforated plate and/or the insulating islands within the conductive perforated plate can provide a sufficiently hard structure for a probe pin to contact for electrical testing with causing little or no damage to the conductive perforated plate. Hence, a crown formed by contact of a probe pin can be avoided or reduced, which can reduce occurrence of spin defects and can reduce residues that could displace metal. Other advantages and benefits may be achieved in various examples.

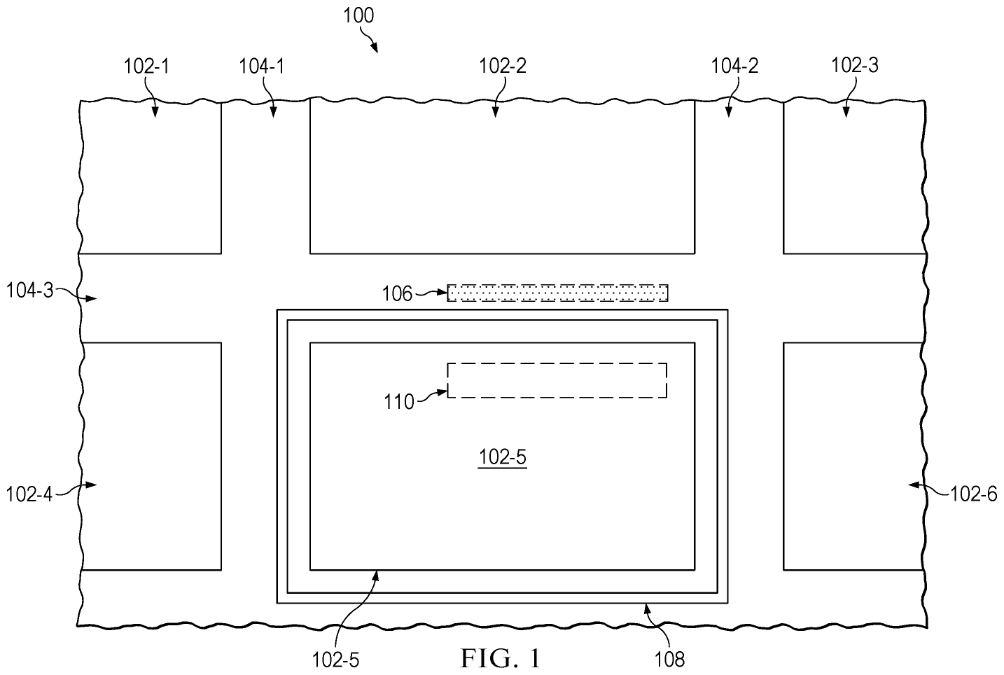

FIG. 1 is a partial layout view of a substrate 100 (e.g., wafer) on which integrated circuit (IC) die areas 102-1, 102-2, 102-3, 102-4, 102-5, 102-6 are fabricated according to some examples. The IC die areas 102-1 through 102-6 are each generally rectangular. Scribe lanes 104-1, 104-2, 104-3 are disposed between the IC die areas 102-1 through 102-6. A device under test (DUT) area 106 is disposed in a scribe lane 104-3 in the illustrated example. The DUT area 106 is adjacent, e.g., the IC die areas 102-2, 102-5. Other DUT areas may be disposed in other scribe lanes. A scribe seal 108 is disposed in various scribe lanes 104-1, 104-2, 104-3 laterally encircling the IC die area 102-5. Although not specifically illustrated, other scribe seals may laterally encircle other respective IC dies. A device cell area 110 is disposed within the IC die area 102-5. The IC die area 102-5 may include multiple device cell areas, and the device cell area 110 is illustrated as an example.

The DUT area 106 may include one or more DUTs that are tested during the fabrication process. The DUT area 106, in some examples, includes one or more conductive perforated plates in an interconnect level. A conductive perforated plate is electrically connected to a respective DUT and may be probed for testing the DUT. The scribe seal 108 may include a stack of metal lines and metal vias laterally encircling the IC die area 102-5 to arrest cracks that may form during dicing and to hermetically seal the layers of the IC die area 102-5. The device cell area 110 may include any type of devices, such as a transistor, a diode, a capacitor, an inductor, a resistor, or other device, that forms in whole or in part an integrated circuit on the IC die area 102-5.

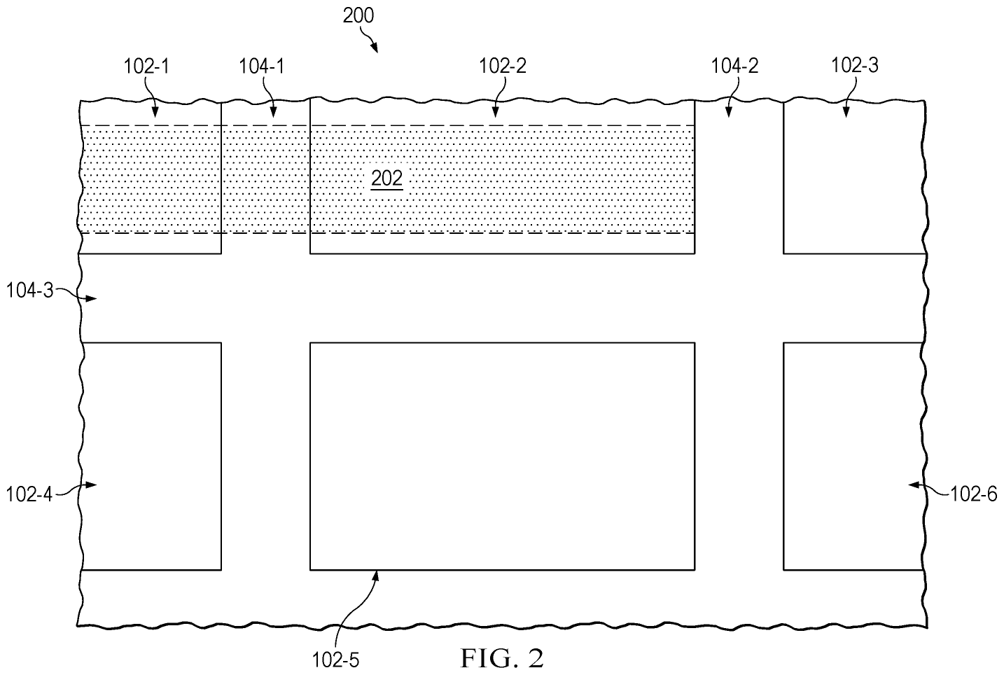

FIG. 2 is a partial layout view of a substrate 200 (e.g., wafer) on which IC die areas 102-1 through 102-6 are fabricated according to some examples. The substrate 200 includes the IC die areas 102-1 through 102-6 and scribe lanes 104-1 through 104-3 as in FIG. 1. A DUT area 202 is disposed at least partially in multiple IC die areas, which in the illustrated example includes IC die areas 102-1, 102-2. The DUT area 202 extends between the IC die areas 102-1, 102-2 through the scribe lane 104-1. Other DUT areas may be disposed in other IC die areas and/or across other scribe lanes. The DUT area 202 may include one or more DUTs that are tested during the fabrication process. The DUT area 202, in some examples, includes one or more conductive perforated plates in an interconnect level. A conductive perforated plate is electrically connected to a respective DUT and can be probed for testing the DUT.

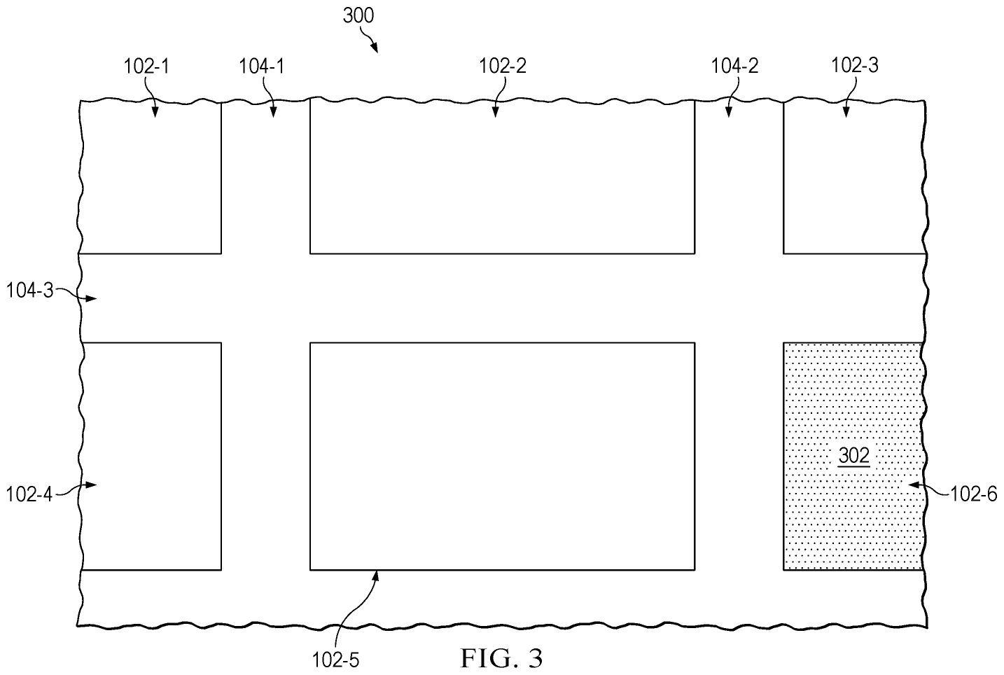

FIG. 3 is a partial layout view of a substrate 300 (e.g., wafer) on which IC die areas 102-1, 102-2, 102-3, 102-4, 102-5 are fabricated according to some examples. The substrate 300 includes the IC die areas 102-1 through 102-5 and scribe lanes 104-1 through 104-3 as in FIG. 1. A DUT area 302 is disposed in an IC die area, which in the illustrated example corresponds to the IC die area 102-6 of previous figures. Other DUT areas may be disposed in other IC die areas. The DUT area 302 may include one or more DUTs that are tested during the fabrication process. The DUT area 302, in some examples, includes one or more conductive perforated plates in an interconnect via level. A conductive perforated plate is electrically connected to a respective DUT and can be probed for testing the DUT.

Although not illustrated in FIGS. 2 and 3, various scribe seals, as for the scribe seal 108 of FIG. 1, may be included in the substrates 200, 300 laterally encircling respective IC die areas 102-1 through 102-6. Further, one or more device cell areas, such as the device cell area 110 of FIG. 1, may be disposed within each IC die area 102-1 through 102-6.

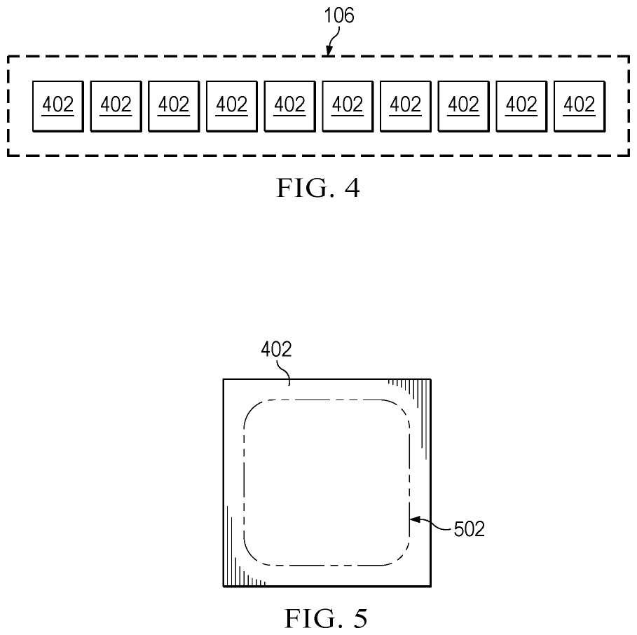

FIG. 4 is a layout view of the DUT area 106 of FIG. 1 according to some examples. A similar layout may be implemented in the DUT areas 202, 302 of FIGS. 2 and 3. The DUT area 106 includes metal lines/pads 402 at a top-most metal level on the substrate 100. In some implementations, such as with wire bonding technology, each metal line/pad 402 includes a metal pad, and may further include or omit a metal line for redistribution. In some implementations, such as with bump technology, each metal line/pad 402 includes a metal line, and may include or omit a metal pad. In the illustrated example, the metal lines/pads 402 are each a metal pad. Any number of metal lines/pads 402 may be implemented. Each metal line/pad 402 may be electrically connected through metal levels and interconnect levels to a respective DUT and may be probed for testing the DUT.

FIG. 5 is a layout view of a metal line/pad 402 in relation to an underlying or overlying conductive perforated plate 502. The conductive perforated plate 502 is disposed in an interconnect level below or above the metal line/pad 402 in the top-most metal level (e.g., which may be in the bond pad topology). When the conductive perforated plate 502 underlies the metal line/pad 402, the metal line/pad 402 is electrically connected to a respective DUT through the conductive perforated plate 502. When the conductive perforated plate 502 overlies the metal line/pad 402, the conductive perforated plate 502 is electrically connected to a respective DUT through the metal line/pad 402. The lateral boundaries of the conductive perforated plate 502 may be within the lateral boundaries of the metal line/pad 402. In such examples, the perimeter of the metal line/pad 402 circumscribes a perimeter of the conductive perforated plate 502. Although the lateral boundaries of the conductive perforated plate 502 are simply illustrated as a rectangle with rounded corners, the lateral boundaries may be in any configuration and may be a given geometric shape or may be irregular.

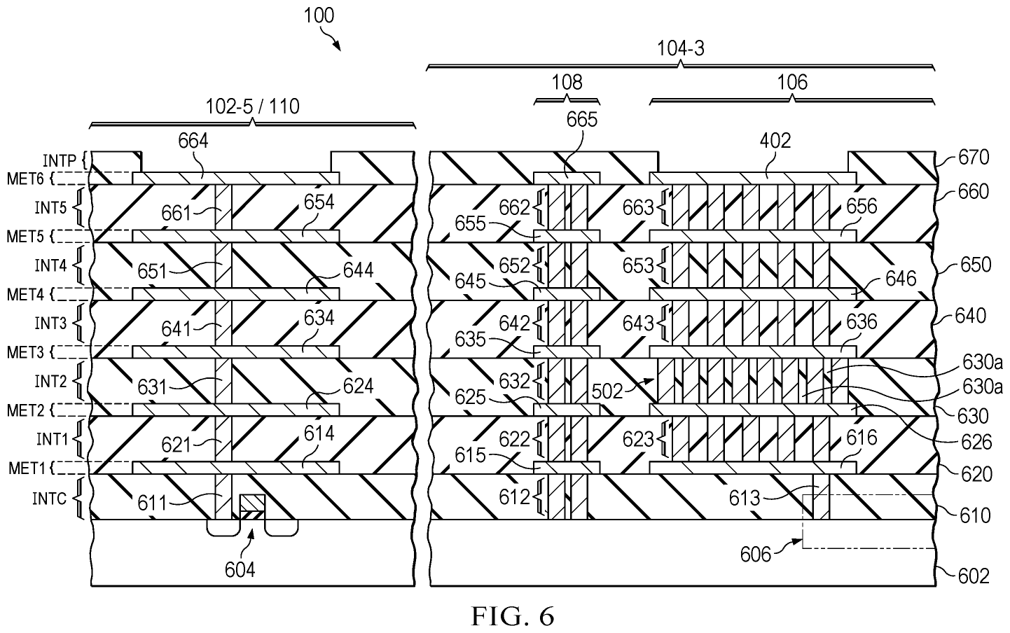

FIG. 6 is a partial cross-sectional view of the substrate 100 of FIG. 1 according to some examples. The cross-sectional view in FIG. 6 is representative of the IC die area 102-5 with the device cell area 110 and illustrates the scribe lane 104-3 with the DUT area 106 and the scribe seal 108. Although described with respect to the substrate 100 of FIG. 1, such description may apply to the substrates 200, 300 of FIGS. 2 and 3. For example, the DUT area 106 in FIG. 6 may represent the DUT area 202, 302, which may further be without reference to a scribe lane 104-3 and/or scribe seal 108.

The substrate 100 includes a semiconductor substrate 602 and interconnect levels and metal levels over the semiconductor substrate 602. In the following examples, an interconnect level is a level that includes metal plugs (e.g., metal contacts and/or metal vias), which may vertically connect components, and is denoted INTx, and a metal level is a level that includes metal lines/pads, which may horizontally connect components, and is denoted METx.

The semiconductor substrate 602 may be or include a bulk semiconductor substrate, a semiconductor-on-insulator (SOI) substrate, or any other appropriate substrate, and in some cases, may include one or more epitaxial layer epitaxially grown on an underlying substrate. In some examples, the semiconductor substrate 602 is or includes a bulk silicon substrate (e.g., wafer), which may further include one or more silicon epitaxial layers epitaxially grown on the bulk silicon substrate.

A device 604 is disposed on and/or over the semiconductor substrate 602 in the device cell area 110 of the IC die area 102-5. The device 604, as illustrated, includes a transistor having a source region, a channel region, and a drain region extending into the semiconductor substrate 602 and having a gate structure disposed on or over the semiconductor substrate 602. The channel region is disposed between the source region and the drain region, and the gate structure is disposed over the channel region. The device 604 may form, in whole or in part, the integrated circuit on the IC die area 102-5. Other devices, including any transistor, diode, capacitor, inductor, resistor, or other device, may be disposed on and/or over the semiconductor substrate 602 in the device cell area 110 and may form, in whole or part, the integrated circuit on the IC die area 102-5. The device 604, in some examples, may be disposed in, in whole or in part, one or more dielectric layers disposed over the semiconductor substrate 602 that are subsequently described.

A DUT 606 is disposed on and/or over the semiconductor substrate 602 in the DUT area 106 in the scribe lane 104-3. The DUT 606 may include any applicable device test structures, such as a transistor, a diode (e.g., p-n junction), a doped region (e.g., a p-type doped region or n-typed doped region), a resistor, a capacitor, an inductor, and/or other electronic device. A number of DUTs may be disposed in the DUT area 106, and the DUTs may be the same type of DUT or different types of DUTs. The DUT 606, in some examples, may be disposed, in whole or in part, in one or more dielectric layers disposed over the semiconductor substrate 602 that are subsequently described.

A pre-metal dielectric (PMD) layer 610 is disposed over the semiconductor substrate 602. The PMD layer 610 may include multiple dielectric layers of a same or different dielectric materials. For example, the PMD layer 610 may include a silicon oxide-based material such as a phosphosilicate glass (PSG), and may further include one or more etch stop layers, such as silicon nitride (SiN) or the like. The PMD layer 610 may be disposed on or over the device 604 in the device cell area 110 and on or over the DUT 606 in the DUT area 106.

Metal contacts 611, 612, 613 are disposed through the PMD layer 610 and make electrical (e.g., ohmic) contact the semiconductor substrate 602 (e.g., possibly, respective doped regions in the semiconductor substrate 602). The metal contacts 611, 612, 613 are in a contact interconnect level (INTC). Metal contact 611 contacts and electrically connects to the device 604 in the device cell area 110. Metal contacts 612 are in the scribe seal 108 and may be trench contacts. Metal contact 613 contacts and electrically connects to the DUT 606 in the DUT area 106. Each of the metal contacts 611, 612, 613 may include a semiconductor-metal compound (e.g., silicide) at the surface of the semiconductor substrate 602, one or more barrier and/or adhesion layers (e.g., titanium nitride (TiN), tantalum nitride (TaN), the like, or a combination thereof) conformally in a respective opening through the PMD layer 610, and a fill metal (e.g., tungsten (W), copper (Cu), the like, or a combination thereof).

Metal line/pad 614, metal line 615, and metal pad 616 are disposed on or over the PMD layer 610 and are in a first metal level (MET1). Metal line/pad 614 is disposed in the device cell area 110 and is disposed over and contacting the metal contact 611. Metal line 615 is disposed in the scribe seal 108 and is disposed over and contacting the metal contacts 612. Metal pad 616 is disposed in the DUT area 106 and is disposed over and contacting the metal contact 613.

A first inter-layer dielectric (ILD1) layer 620 is disposed on or over the metal line/pad 614, metal line 615, and metal pad 616. Metal vias 621, 622, 623 are disposed through the ILD1 layer 620 and are in a first via interconnect level (INT1). Metal via 621 contacts the metal line/pad 614 in the device cell area 110. Metal vias 622 contact the metal line 615 in the scribe seal 108 and may be trench vias. Metal vias 623 contact the metal pad 616 in the DUT area 106. A metal line/pad 624, a metal line 625, and a metal pad 626 are disposed on or over the ILD1 layer 620 and are in a second metal level (MET2). The metal line/pad 624 is disposed in the device cell area 110 and is disposed over and contacting the metal via 621. The metal line 625 is disposed in the scribe seal 108 and is disposed over and contacting the metal vias 622. The metal pad 626 is disposed in the DUT area 106 and is disposed over and contacting the metal vias 623.

A second inter-layer dielectric (ILD2) layer 630 is disposed on or over the metal line/pad 624, metal line 625, and metal pad 626. Metal vias 631, 632 and the conductive perforated plate 502 are disposed through the ILD2 layer 630 and are in a second via interconnect level (INT2). Metal via 631 contacts the metal line/pad 624 in the device cell area 110. Metal vias 632 contact the metal line 625 in the scribe seal 108 and may be trench vias. The conductive perforated plate 502 contacts the metal pad 626 in the DUT area 106. The perimeter of the metal pad 626 may circumscribe the perimeter of the conductive perforated plate 502, such as the metal line/pad 402 in FIG. 5. A metal line/pad 634, a metal line 635, and a metal pad 636 are disposed on or over the ILD2 layer 630 and are in a third metal level (MET3). The metal line/pad 634 is disposed in the device cell area 110 and is disposed over and contacting the metal via 631. The metal line 635 is disposed in the scribe seal 108 and is disposed over and contacting the metal vias 632. The metal pad 636 is disposed in the DUT area 106 and is disposed over and contacting the conductive perforated plate 502. The perimeter of the metal pad 636 may circumscribe the perimeter of the conductive perforated plate 502, such as the metal line/pad 402 in FIG. 5. Insulating islands 630a of the ILD2 layer 630 are disposed laterally within the conductive perforated plate 502, as described in more detail subsequently.

A third inter-layer dielectric (ILD3) layer 640 is disposed on or over the metal line/pad 634, metal line 635, and metal pad 636. Metal vias 641, 642, 643 are disposed through the ILD3 layer 640 and are in a third via interconnect level (INT3). Metal via 641 contacts the metal line/pad 634 in the device cell area 110. Metal vias 642 contact the metal line 635 in the scribe seal 108 and may be trench vias. Metal vias 643 contact the metal pad 636 in the DUT area 106. A metal line/pad 644, a metal line 645, and a metal pad 646 are disposed on or over the ILD3 layer 640 and are in a fourth metal level (MET4). The metal line/pad 644 is disposed in the device cell area 110 and is disposed over and contacting the metal via 641. The metal line 645 is disposed in the scribe seal 108 and is disposed over and contacting the metal vias 642. The metal pad 646 is disposed in the DUT area 106 and is disposed over and contacting the metal vias 643.

A fourth inter-layer dielectric (ILD4) layer 650 is disposed on or over the metal line/pad 644, metal line 645, and metal pad 646. Metal vias 651, 652, 653 are disposed through the ILD4 layer 650 and are in a fourth via interconnect level (INT4). Metal via 651 contacts the metal line/pad 644 in the device cell area 110. Metal vias 652 contact the metal line 645 in the scribe seal 108 and may be trench vias. Metal vias 653 contact the metal pad 646 in the DUT area 106. A metal line/pad 654, a metal line 655, and a metal pad 656 are disposed on or over the ILD4 layer 650 and are in a fifth metal level (MET5). The metal line/pad 654 is disposed in the device cell area 110 and is disposed over and contacting the metal via 651. The metal line 655 is disposed in the scribe seal 108 and is disposed over and contacting the metal vias 652. The metal pad 656 is disposed in the DUT area 106 and is disposed over and contacting the metal vias 653.

A fifth inter-layer dielectric (ILD5) layer 660 is disposed on or over the metal line/pad 654, metal line 655, and metal pad 656. Metal vias 661, 662, 663 are disposed through the ILD5 layer 660 and are in a fifth via interconnect level (INT5). Metal via 661 contacts the metal line/pad 654 in the device cell area 110. Metal vias 662 contact the metal line 655 in the scribe seal 108 and may be trench vias. Metal vias 663 contact the metal pad 656 in the DUT area 106. A metal line/pad 664, a metal line 665, and a metal line/pad 402 are disposed on or over the ILD5 layer 660 and are in a sixth metal level (MET6), which is a top-most metal level in the illustrated example. The metal line/pad 664 is disposed in the device cell area 110 and is disposed over and contacting the metal via 661. The metal line 665 is disposed in the scribe seal 108 and is disposed over and contacting the metal vias 662. The metal line/pad 402 is disposed in the DUT area 106 and is disposed over and contacting the metal vias 663.

The ILD1, ILD2, ILD3, ILD4, ILD5 layers 620, 630, 640, 650, 660 may each include multiple dielectric layers of a same or different dielectric materials. For example, the ILD1, ILD2, ILD3, ILD4, ILD5 layers 620, 630, 640, 650, 660 may each include a silicon oxide-based material such as formed from tetraethyl orthosilicate (TEOS), high density plasma (HDP) oxide, the like, or a combination thereof, and may further include one or more etch stop layers, such as silicon nitride (SiN) or the like. The INT1, INT2, INT3, INT4, and INT5 (including respective metal vias and conductive perforated plate 502) may include one or more barrier and/or adhesion layers (e.g., titanium nitride (TiN), tantalum nitride (TaN), the like, or a combination thereof) conformally in a respective opening through the respective ILD layer, and a fill metal (e.g., tungsten (W), copper (Cu), the like, or a combination thereof). The MET1, MET2, MET3, MET4, MET5, and MET6 (including respective metal lines/pads) may each include one or more barrier and/or adhesion layers (e.g., titanium nitride (TiN), tantalum nitride (TaN), the like, or a combination thereof) and a bulk metal (e.g., aluminum (Al), copper (Cu), the like, or a combination thereof).

A passivation dielectric layer 670 is disposed on or over the metal line/pad 664, metal line 665, and metal line/pad 402. The passivation dielectric layer 670 may include multiple dielectric layers of a same or different dielectric materials. The passivation dielectric layer 670 may include silicon nitride (SiN), silicon oxynitride (SiON), the like, or a combination thereof. In the illustrated example, the substrate 100 can be implemented for, e.g., wire bonding technology. As such, an opening through the passivation dielectric layer 670 exposes the metal line/pad 664, and another opening through the passivation dielectric layer 670 exposes the metal line/pad 402. In other examples, a passivation via interconnect level (INTP) may be implemented through the passivation dielectric layer 670 and contacting the MET6 (e.g., the metal line/pad 664 and metal line/pad 402). Such examples may be implemented in, e.g., bump technology where UBMs are formed over and contacting the INTP. Although the level of INTP is illustrated in FIG. 6, no plugs of the INTP are shown in FIG. 6.

The example of FIG. 6 illustrates various aspects according to examples. Other examples may include more or fewer INTs, more or fewer METs, and more or fewer ILDs. The device 604 with corresponding connecting metal contact, metal vias, and metal lines/pads is shown for context, and any device(s) with any interconnecting metal structure may be implemented. Additionally, one or more conductive perforated plates may be implemented in other respective INTs. A conductive perforated plate may be in any of the INTs (e.g., INTC, INT1, . . . INT5, and/or INTP) and may be probed for testing the respective DUT 606 during a fabrication process.

The scribe seal 108 includes a stack of metal lines, metal vias, and metal contacts, as shown in FIG. 6. The metal lines 615, 625, 635, 645, 655, 665 of the scribe seal 108 laterally circumscribe a respective IC die area, which in this example is the IC die area 102-5. Multiple discrete metal contacts or vias may be in a respective INT and may have lateral placements within the respective INT separate from each other metal contact or via and aligned laterally generally corresponding to the respective overlying and underlying (where applicable) metal lines that the metal contacts or vias contact. The scribe seal 108 can prevent cracks from mechanical singulation of the IC dies from propagating into the device cell area(s) 110 of the IC die.

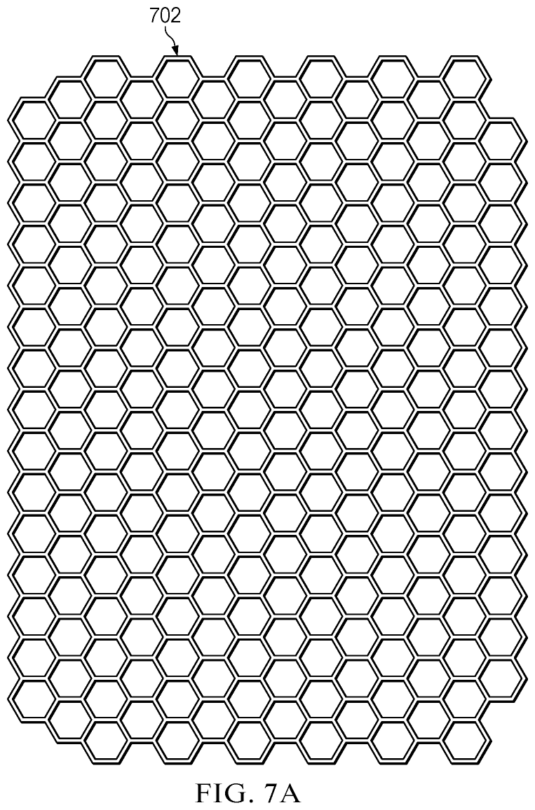

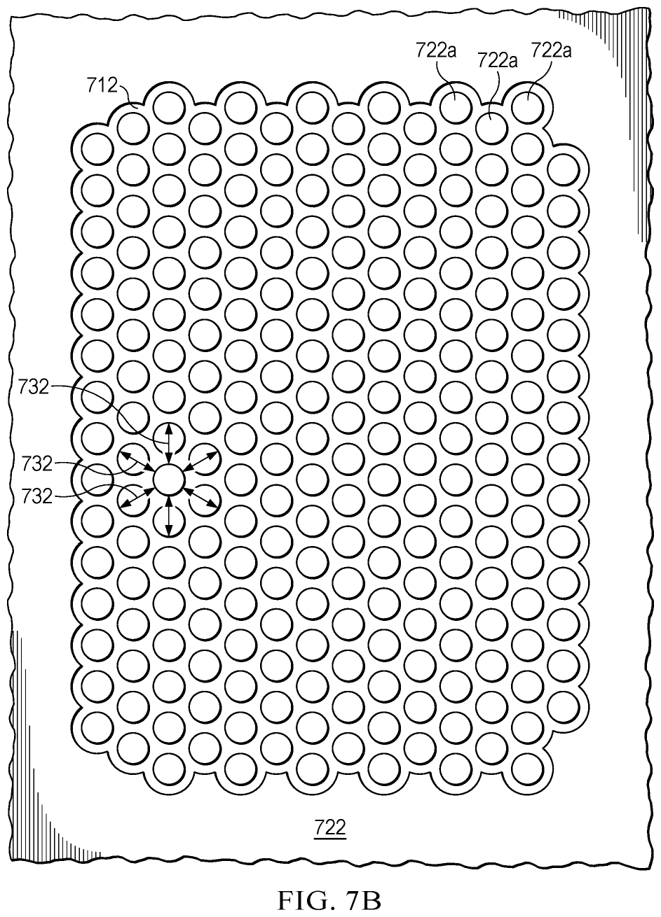

FIG. 7A is a layout view of a photomask 702 for forming a conductive perforated plate, and FIG. 7B is a layout view of a resulting conductive perforated plate 712 according to some examples. The layout view of the conductive perforated plate 712 (and similar layout views described subsequently) is in a plane parallel to a top surface of the semiconductor substrate 602 over which the conductive perforated plate 712 is implemented. Generally, the photomask 702 is used in a photolithography process to pattern a photoresist that is disposed on or over a dielectric layer 722. Etching is performed to transfer the pattern of the photoresist to the dielectric layer 722 and to form an opening through the dielectric layer 722 having the pattern of the photoresist. The opening is then filled, such as by metal deposition followed by metal planaraization (e.g., a chemical mechanical polish (CMP)), to form the conductive perforated plate 712. In the illustrated example, the lines of the photomask 702 correspond to respective trenches etched through the dielectric layer 722. The lines of the photomask 702 may be opaque or transparent depending on the tone (e.g., positive or negative) of the photoresist.

The photomask 702 has a honeycomb pattern of hexagons, and the resulting conductive perforated plate 712 is a honeycomb pattern. The photolithography and etch processes may result in some rounding of corners, such as illustrated in the conductive perforated plate 712 in FIG. 7B. The conductive perforated plate 712 is generally a metal structure that is unitary within the given INT. Lateral boundaries of the conductive perforated plate 712 are irregular. Insulating islands 722a of the dielectric layer 722 are disposed within the metal structure of the conductive perforated plate 712. The insulating islands 722a are generally arranged in a hexagonal array, although in other examples, the insulating islands 722a may be arranged differently.

In the array arrangement of FIG. 7B, the insulating islands 722a are disposed with a lateral pitch 732 between neighboring pairs of insulating islands 722a. For a given neighboring pair of insulating islands 722a, a lateral pitch 732 includes a lateral dimension (e.g., diameter) of one insulating island 722a of the neighboring pair of insulating islands 722a and a lateral dimension of the conductive perforated plate 712 disposed between the neighboring pair of insulating islands 722a along that lateral pitch 732. The lateral pitch may also be the center-to-center distance between nearest-neighbor insulating islands 722a. In some examples, the lateral dimension of the conductive perforated plate 712 disposed between the neighboring pair of insulating islands 722a along a lateral pitch 732 may be less than or equal to 0.30 μm (e.g., equal to 0.24 μm), and more particularly, in a range from 0.20 μm to 0.30 μm; the lateral dimension of an insulating island 722a along a lateral pitch 732 may be greater than or equal to 0.7 μm (e.g., about 0.85 μm), and more particularly, in a range from 0.70 μm to 2.75 μm; and the lateral pitch 732 may be in a range from 1.1 μm to 3.0 μm. The lateral pitch 732 and lateral dimension of the conductive perforated plate 712 along the lateral pitch 732 may be chosen to follow design rules for the INT (e.g., INT2 in the example of FIG. 6) regarding critical dimension and filling, for example.

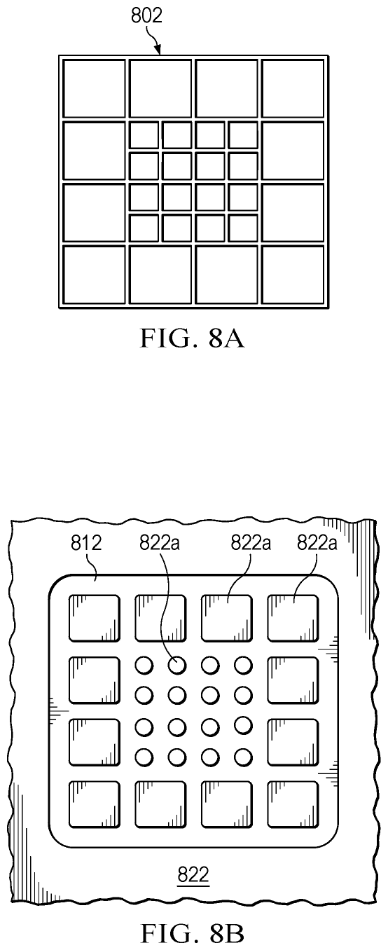

FIG. 8A is a layout view of a photomask 802 for forming a conductive perforated plate 812, and FIG. 8B is a layout view of the resulting conductive perforated plate 812 according to some examples. Generally, the photomask 802 is used in a photolithography process such as described above. In the illustrated example, the lines of the photomask 802 correspond to respective trenches etched into a dielectric layer 822. The lines of the photomask 802 may be opaque or transparent depending on the tone (e.g., positive or negative) of the photoresist.

The photomask 802 has a pattern of adjoining rectangles arranged generally in a grid, and the resulting conductive perforated plate 812 is a pattern of adjoining rectangles arranged generally in a grid. Smaller rectangles (which result in a greater density of number of rectangles) are disposed in a central region of the pattern of the photomask 802 and the conductive perforated plate 812. The photolithography and etch processes may result in some rounding of corners, such as illustrated in the conductive perforated plate 812 in FIG. 8B. The conductive perforated plate 812 is generally a metal structure that is unitary within the given INT. In the illustrated example, lateral boundaries of the conductive perforated plate 812 form generally a rectangle with rounded corners. Insulating islands 822a of the dielectric layer 822 are disposed within the metal structure of the conductive perforated plate 812. Due to the smaller rectangles (with greater density) in the central region of the pattern of the photomask 802, a higher density of metal, or a higher ratio of metal to insulating material of the insulating islands 822a, is formed in a central region of the conductive perforated plate 812, such as where a probe pin is more likely to make contact. Typically, the mask pattern is designed to ensure that no feature produced by the resulting photoresist pattern violates the design rules for that INT.

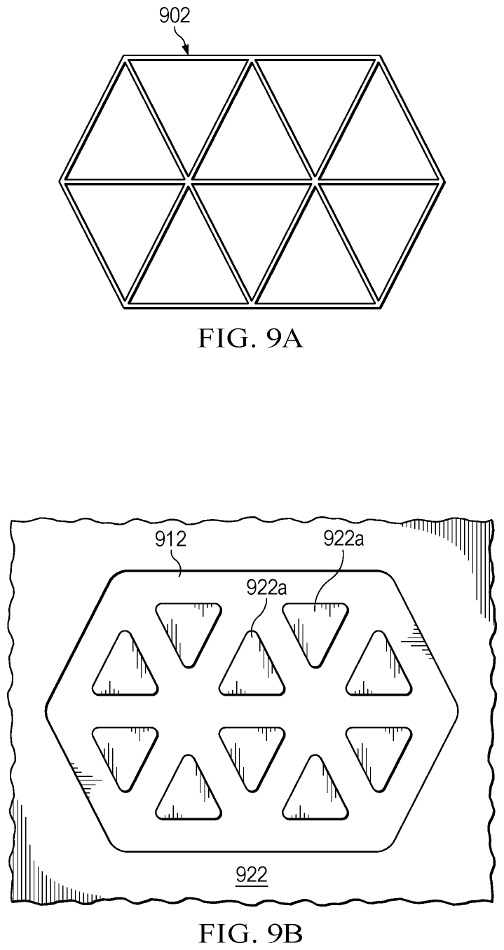

FIG. 9A is a layout view of a photomask 902 for forming a conductive perforated plate 912, and FIG. 9B is a layout view of the resulting conductive perforated plate 912 according to some examples. Generally, the photomask 902 is used in a photolithography process such as described above. In the illustrated example, the lines of the photomask 902 correspond to respective trenches etched through a dielectric layer 922. The lines of the photomask 902 may be opaque or transparent depending on the tone (e.g., positive or negative) of the photoresist.

The photomask 902 has a pattern of adjoining triangles, and the resulting conductive perforated plate 912 is a pattern of adjoining triangles. The photolithography and etch processes may result in some rounding of corners, such as illustrated in the conductive perforated plate 912 in FIG. 9B. The conductive perforated plate 912 is generally a metal structure that is unitary within the given INT. In the illustrated example, lateral boundaries of the conductive perforated plate 912 form generally a hexagon with rounded corners. Insulating islands 922a of the dielectric layer 922 are disposed within the metal structure of the conductive perforated plate 912.

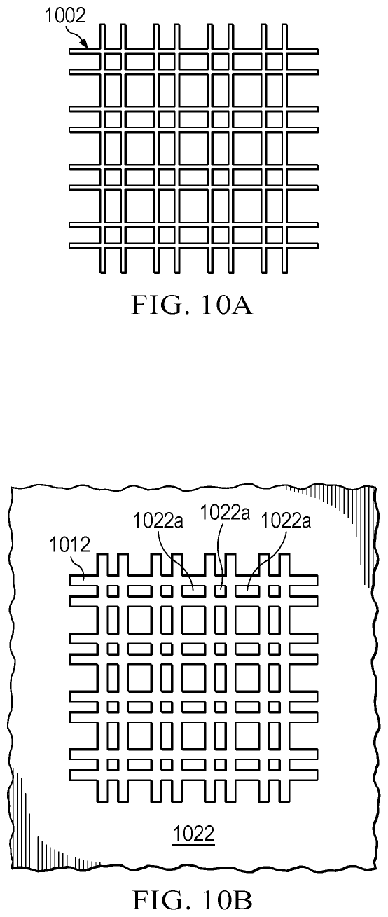

FIG. 10A is a layout view of a photomask 1002 for forming a conductive perforated plate 1012, and FIG. 10B is a layout view of the resulting conductive perforated plate 1012 according to some examples. Generally, the photomask 1002 is used in a photolithography process such as described above. In the illustrated example, the lines of the photomask 1002 correspond to respective trenches etched through a dielectric layer 1022. The lines of the photomask 1002 may be opaque or transparent depending on the tone (e.g., positive or negative) of the photoresist.

The photomask 1002 has a grid pattern, and the resulting conductive perforated plate 1012 is a grid pattern. Pitches between neighboring parallel lines (which correspond to pitches between neighboring trenches) may be equal throughout a given x and/or y-direction of the layout of the pattern of the photomask 802 or may vary (e.g., alternate between two or more pitches) throughout a given x and/or y-direction. The photolithography and etch processes may result in some rounding of corners, such as illustrated in the conductive perforated plate 1012 in FIG. 10B. The conductive perforated plate 1012 is generally a metal structure that is unitary within the given INT. In the illustrated example, lateral boundaries of the conductive perforated plate 1012 may have a pattern that may not necessarily correspond to a simple geometric shape. Insulating islands 1022a of the dielectric layer 1022 are disposed within the metal structure of the conductive perforated plate 1012.

The photomasks 702, 802, 902, 1002 of FIGS. 7A, 8A, 9A, and 10A may include adjustments for lines to accommodate for diffraction during the exposure (e.g., optical proximity correction). Such adjustments may include line width adjustments, fillets, and/or serifs. The resulting conductive perforated plate 712, 812, 912, 1012 can have rounding at intersecting trenches resulting from diffraction during the exposure using the respective photomask 702, 802, 902, 1002. Where corners are indicated in a photomask 702, 802, 902, 1002, a rounded edge may be formed from the resulting exposure. This may cause insulating islands to have rounded corners and/or be an ovaloid shape or circular shape.

The conductive perforated plate 712, 812, 912, 1012 of FIGS. 7B, 8B, 9B, and/or 10B may be in the INT2 (such as the conductive perforated plate 502 in FIG. 6) or another INT, and the dielectric layer 722, 822, 922, 1022 of FIGS. 7B, 8B, 9B, and/or 10B may be the ILD2 layer 630 or another ILD layer. In some examples, a surface area ratio of the top surface of the conductive perforated plate 502 (e.g., conductive perforated plate 712, 812, 912, 1012) to the top surfaces of the insulating islands 630a (e.g., insulating islands 722a, 822a, 922a, 1022a) within the conductive perforated plate 502 may be in a range from 0.15:1 to 1.1:1. The surface area ratio may be sufficient to permit a low resistance contact between a probe pin and the conductive perforated plate 502.

In some examples, the conductive perforated plate 502 comprises a metal having a hardness greater than aluminum or an aluminum alloy (such as aluminum copper (Al₁₋ₓCuₓ, where x≤0.02), aluminum silicon (AlSi), or the like). For example, the top surface of the conductive perforated plate 502 may be or include tungsten. In some examples, the conductive perforated plate 502 includes tungsten on a barrier layer of titanium nitride or tantalum nitride. In other examples, the top surface of the conductive perforated plate 502 may be or include another metal having a hardness greater than aluminum or an aluminum alloy, such as copper. Tungsten is relatively inert at ambient conditions, which can provide flexibility on timing of the electrical test since tungsten can be exposed to an ambient environment with little to no reaction with a gas of the ambient environment. Further, tungsten is likely to be abraded less than aluminum, which may reduce the amount of residues on the conductive perforated plate 502 and probe pin 1104 relative to previous testing. Additionally, in some examples, the conductive perforated plate 502 and arrangement of insulating islands 630a in the conductive perforated plate 502 may have a recognizable arrangement for an auto-alignment process for aligning testing equipment to the conductive perforated plate 502.

Generally, the structure of the conductive perforated plate 502 (including having the insulating islands 630a through the conductive perforated plate 502) and/or the metal of the conductive perforated plate 502 can lead to greater robustness for electrical testing. The conductive perforated plate 502 and insulating islands 630a can reduce punch through of a probe pin during testing and can reduce occurrence and/or magnitude of a footprint and crown resulting from contact by the probe pin. The reduced occurrence and/or magnitude of footprints and crowns can reduce spin defects. A depth and a rim height of a crown can be a function of a lateral pitch, such as the lateral pitch 732 in FIG. 7B, for a given lateral dimension (e.g., critical dimension) of the conductive perforated plate. For example, in the context of the conductive perforated plate 712 of FIG. 7B, respective magnitudes of a depth and a rim height of a crown were observed to generally decrease with decreasing lateral pitch 732 for a given lateral dimension of the conductive perforated plate 712 between neighboring insulating islands 722a.

Additionally, including the insulating islands 630a through the conductive perforated plate 502 may permit the conductive perforated plate 502 to follow design rules of the given INT. The insulating islands 630a may permit the conductive perforated plate 502 to follow, e.g., a critical dimension design rule between neighboring insulating islands 630a such that the conductive perforated plate 502 may avoid being a design rule violating large conductive pad. The insulating islands 630a may also reduce dishing of the conductive perforated plate 502 that may occur with a planarization process, such as CMP. Without the insulating islands 630a, a plate having a continuous metal surface throughout the lateral bounds of the conductive perforated plate 502 may suffer from significant dishing from a CMP.

Further, cracking of the ILD layer in which the conductive perforated plate 502 is disposed as a result of contact of a probe pin to the conductive perforated plate 502 may be low. The formation of the conductive perforated plate 502 and insulating islands 630a may be easily compatible with processing to form an interconnect level.

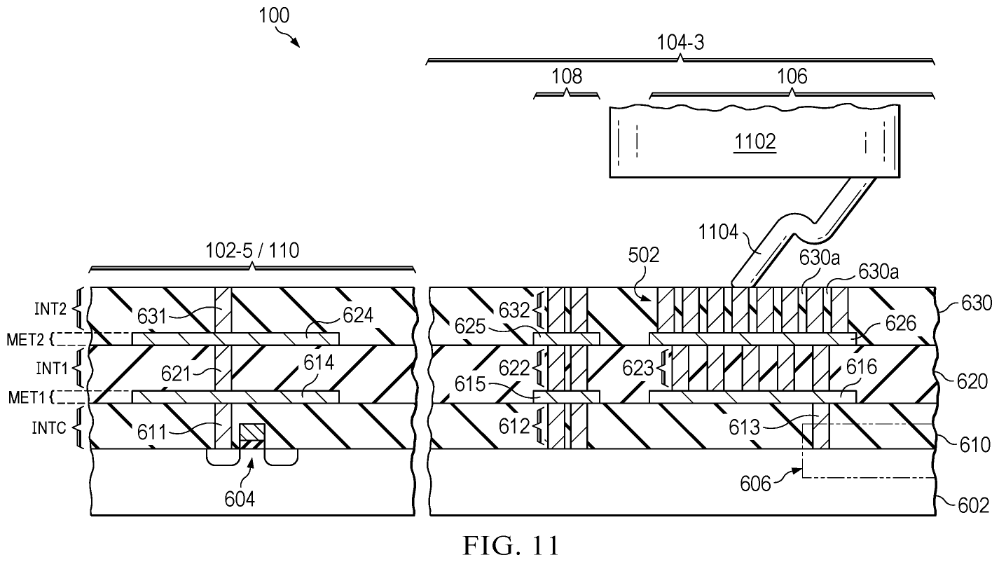

FIG. 11 is a partial cross-sectional view of the substrate 100 of FIG. 1 during fabrication according to some examples. FIG. 11 illustrates electrical testing of the DUT 606. The electrical test of the DUT 606 occurs, in this example, after formation of the INT2, which includes the conductive perforated plate 502, and before formation of the MET3. A test probe 1102 includes a probe pin 1104. The test probe 1102 is aligned with the DUT area 106 in the scribe lane 104-3, and the test probe 1102 is moved vertically such that the tip of the probe pin 1104 contacts the conductive perforated plate 502. In some instances, the probe pin 1104 may move laterally with respect to the surface of the conductive perforated plate 502, thus “scrubbing” the surface. With the probe pin 1104 contacting the conductive perforated plate 502, an electrical test is conducted on the DUT 606 via the test probe 1102 and the conductive perforated plate 502. The test probe 1102 may include other probe pins that simultaneously and/or sequentially contact other conductive perforated plates (such as the conductive perforated plate 502) to conduct electrical tests of the DUT 606 and/or other DUTs.

A conductive perforated plate may be disposed in or formed in any INT (e.g., INTC, INT1, . . . INT5, INTP) for performing an electrical test of a DUT. In the example of FIGS. 6 and 11, the conductive perforated plate 502 is disposed in and is formed in the INT2.

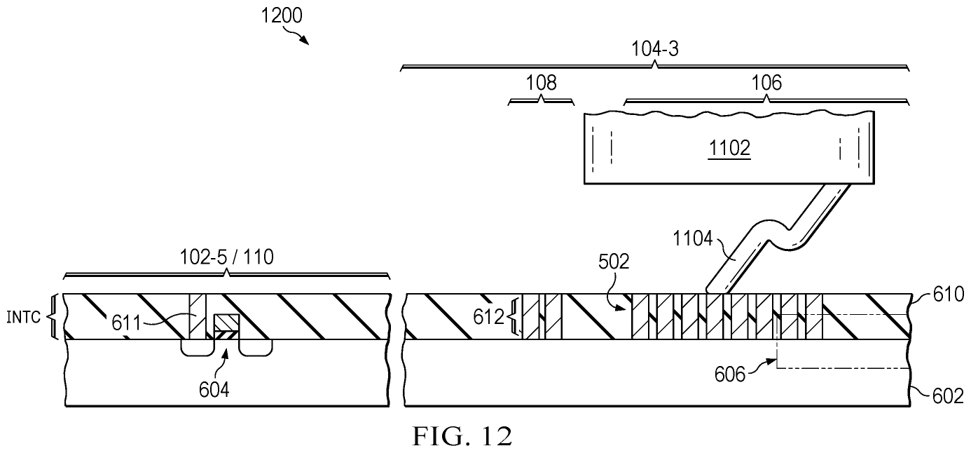

FIG. 12 is a partial cross-sectional view of a substrate 1200, in which a conductive perforated plate 502 is disposed in and formed in the INTC, during fabrication according to some examples. The conductive perforated plate 502 is disposed through the PMD layer 610 and contacts and electrically connects to the DUT 606 in the DUT area 106. In FIG. 12, the electrical test of the DUT 606 occurs after formation of the INTC and before formation of the MET1. The test probe 1102 is aligned with the DUT area 106 in the scribe lane 104-3, and the test probe 1102 is moved vertically such that the tip of the probe pin 1104 contacts the conductive perforated plate 502. In some instances, the probe pin 1104 may move laterally with respect to the surface of the conductive perforated plate 502, thus “scrubbing” the surface. With the probe pin 1104 contacting the conductive perforated plate 502, an electrical test is conducted on the DUT 606 via the test probe 1102 and the conductive perforated plate 502.

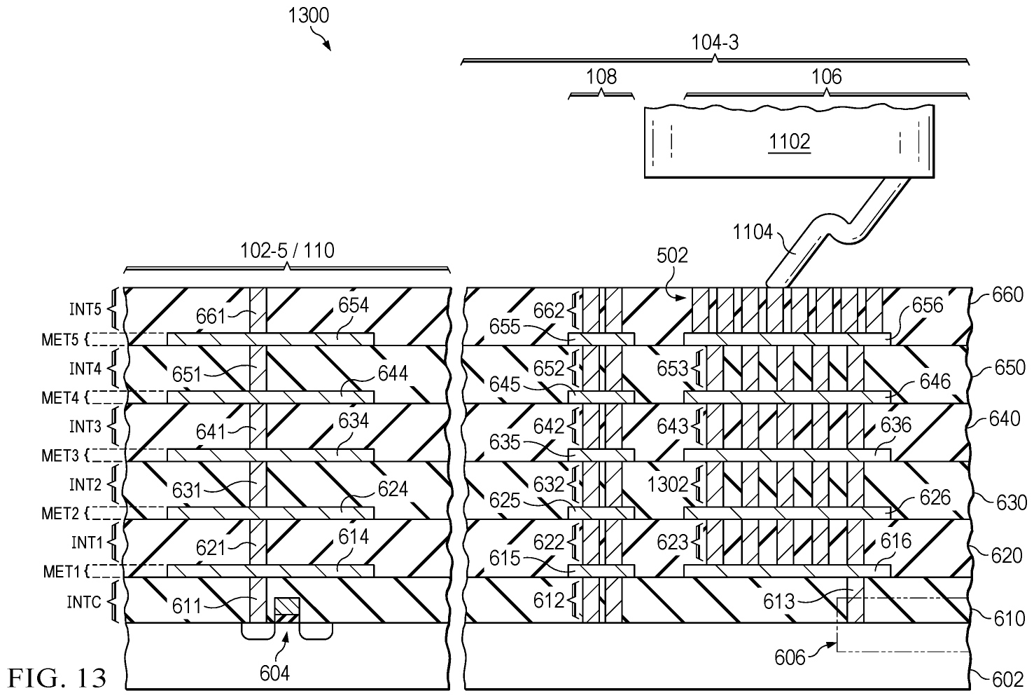

FIG. 13 is a partial cross-sectional view of a substrate 1300, in which a conductive perforated plate 502 is disposed in and formed in the INT5, during fabrication according to some examples. The conductive perforated plate 502 is disposed through the ILD5 layer 660 and contacts the metal pad 656. Further, metal vias 1302 are disposed through the ILD2 layer 630 and are in the INT2. The metal vias 1302 contact the metal pad 626 in the DUT area 106. The metal pad 636 is disposed in the DUT area 106 and is disposed over and contacting the metal vias 1302. In FIG. 13, the electrical test of the DUT 606 occurs after formation of the INT5 and before formation of the MET6. The test probe 1102 is aligned with the DUT area 106 in the scribe lane 104-3, and the test probe 1102 is moved vertically such that the probe pin 1104 contacts the conductive perforated plate 502. In some instances, the probe pin 1104 may move laterally with respect to the surface of the conductive perforated plate 502, thus “scrubbing” the surface. With the probe pin 1104 contacting the conductive perforated plate 502, an electrical test is conducted on the DUT 606 via the test probe 1102 and the conductive perforated plate 502.

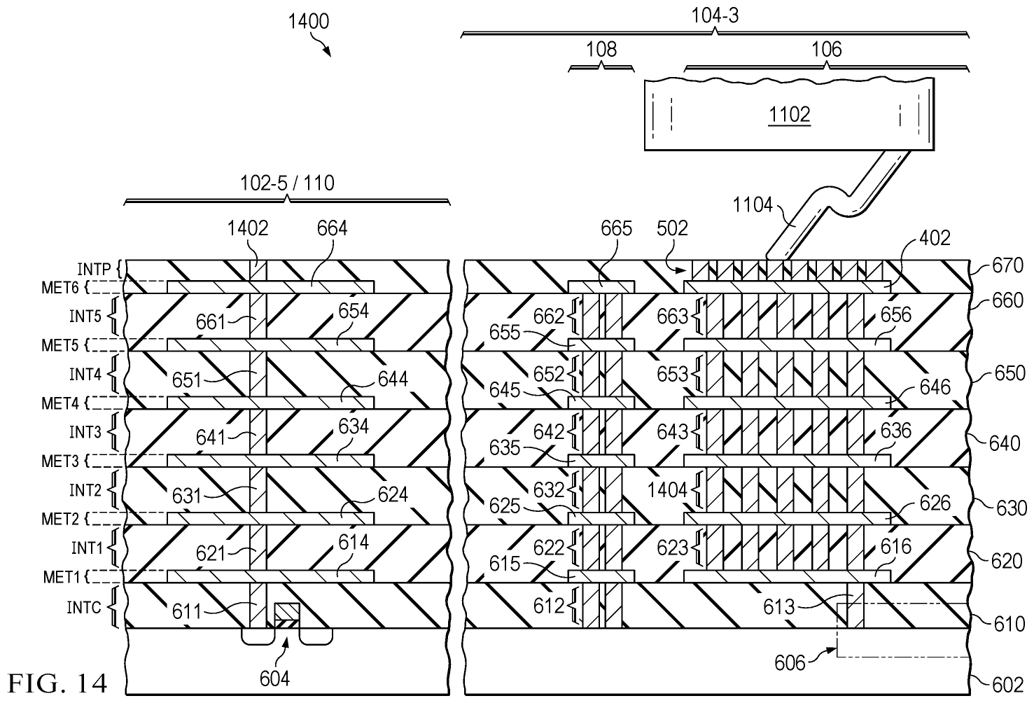

FIG. 14 is a partial cross-sectional view of a substrate 1400, in which a conductive perforated plate 502 is disposed in and formed in the INTP, during fabrication according to some examples. The conductive perforated plate 502 is disposed through the passivation dielectric layer 670 and contacts the metal line/pad 402. Additionally, one or more metal vias 1402 in the IC die area 102-5 is disposed through the passivation dielectric layer 670 and contacts the metal line/pad 664. The metal via(s) 1402 may be for providing an electrical connection between a subsequently formed UBM and the metal line/pad 664. Further, metal vias 1404 are disposed through the ILD2 layer 630 and are in the INT2. The metal vias 1404 contact the metal pad 626 in the DUT area 106. The metal pad 636 is disposed in the DUT area 106 and is disposed over and contacting the metal vias 1404. In FIG. 14, the electrical test of the DUT 606 occurs after formation of the INTP and before, e.g., formation of a UBM. The test probe 1102 is aligned with the DUT area 106 in the scribe lane 104-3, and the test probe 1102 is moved such that the probe pin 1104 contacts the conductive perforated plate 502. With the probe pin 1104 contacting the conductive perforated plate 502, an electrical test is conducted on the DUT 606 via the test probe 1102 and the conductive perforated plate 502.

The testing of FIG. 14, in some implementations, may be performed following completion of processing of the substrate 1400 at a given facility before the substrate 1400 is transported to another facility for processing for UBMs and bumps. In some examples, such as where tungsten is used to implement the conductive perforated plate 502 and the metal via(s) 1402, low reactivity of the conductive perforated plate 502 and the metal via(s) 1402 may permit the conductive perforated plate 502 and the metal via(s) 1402 to be exposed to an ambient environment during transport with little adverse effect.

Other examples may include one or more conductive perforated plates disposed in one or more INTs. The examples of FIGS. 6, 11, 12, 13, and 14 are to show different INTs in which a conductive perforated plate may be disposed and to show electrical tests performed using such conductive perforated plate. Multiple conductive perforated plates in respective interconnect levels may be implemented to electrically connect to a given DUT, and as such, the DUT may be tested at multiple times during fabrication. For example, a first conductive perforated plate can be formed in INT1, which is used for testing the DUT immediately following front-end-of-the-line (FEOL) processing, and a second conductive plate can be formed in INT5 or INTP, which can be used for testing the DUT following metal processing prior to wire bonding or bump processing. Using a conductive perforated plate in INT1 may permit a faulty substrate to be scrapped early in the fabrication process, and using a conductive perforated plate in INT5 or INTP may permit testing to ensure a functional circuit is fabricated.

Additionally, as previously described, the testing in the examples of FIGS. 11 through 14 may be implemented on the substrates 200, 300 of FIGS. 2 and 3. For example, the DUT area 106 in FIGS. 11 through 14 may be the DUT area 202, 302, which may further be without reference to a scribe lane 104-3 and/or scribe seal 108. Other modifications may be implemented.

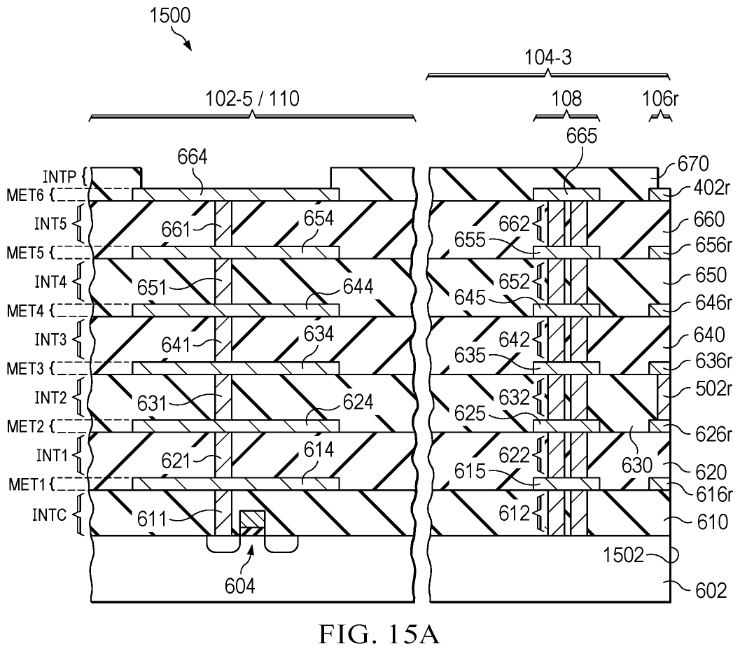

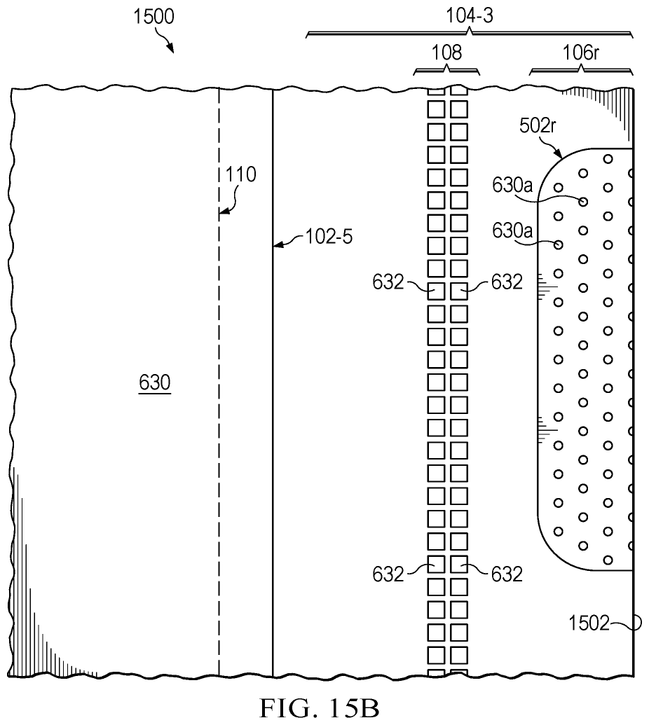

FIGS. 15A and 15B are a partial cross-sectional view and a partial layout view of an IC die 1500 singulated from the substrate 100 of FIG. 1 according to some examples. The layout view of FIG. 15B is at the INT2. Metal vias in the INT2 (e.g., metal via 631) in the IC die area 102-5 are omitted in FIG. 15B for simplicity.

IC dies are singulated from the substrate 100 of FIG. 1. The IC die 1500 is an example of such IC dies. The singulation may be by sawing, dicing, laser cutting, or the like. The IC die 1500 includes the components formed in the IC die area 102-5, including the device cell area 110. The IC die 1500 further includes remnant scribe lanes, including remnant scribe lane 104-3r. The scribe seal 108 in this example remains circumscribing the IC die area 102-5 and is disposed at least in part in the remnant scribe lane 104-3r. A remnant DUT area 106r remains in the remnant scribe lane 104-3r and along an edge 1502 of the IC die 1500, which may be a kerf edge from the singulation.

As illustrated, remnant portions 616r, 626r, 636r, 646r, 656r, 402r of metal pads 616, 626, 636, 646, 656 and metal line/pad 402 may remain in the remnant DUT area 106r. Additionally, a remnant conductive perforated plate 502r remains in the remnant DUT area 106r. A number of insulating islands 630a may remain within the remnant conductive perforated plate 502r. The singulation of the IC die 1500 may cause portions of components in the DUT area 106 to be removed, and some components, in whole or in part, may remain in the remnant DUT area 106r after singulation. Other components, such as metal vias and/or the DUT 606, may remain in the remnant DUT area 106r after singulation. The DUT 606 may remain electrically connected to the remnant conductive perforated plate 502r. Remnant portions may remain contacting and/or electrically connected as described above with respect to the corresponding components prior to singulation.

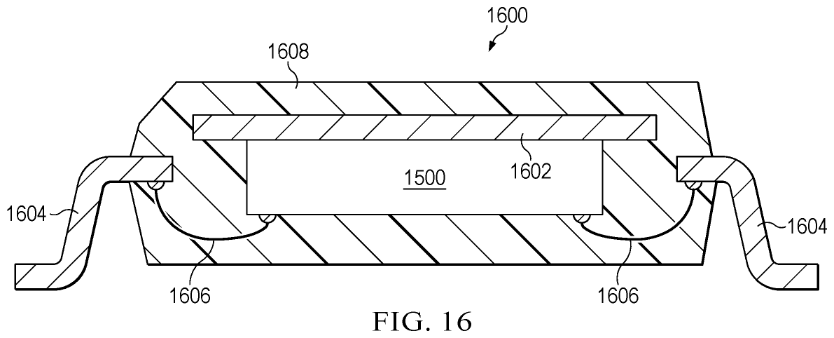

FIG. 16 is a cross-sectional view of an IC package 1600 according to some examples. The IC die 1500 is packaged in the IC package 1600. The IC package 1600 also includes a leadframe 1602 with leads 1604. The IC die 1500 is mechanically attached (e.g., by an adhesive) to the leadframe 1602. Wires 1606 are bonded between the IC die 1500 (e.g., respective metal line/pads 664) and the leads 1604. Hence, functional circuits on the IC die 1500 may be electrically connected externally via the leads 1604 and wires 1606. The IC die 1500 and leadframe 1602 are encapsulated with an encapsulant 1608, such as a molding compound. Other examples of an IC package include a quad flat no lead (QFN) package, a ball grid array (BGA) package, a single inline package (SIP), a dual inline package (DIP), a wafer-level chip-scale package (WCSP), or another IC package.

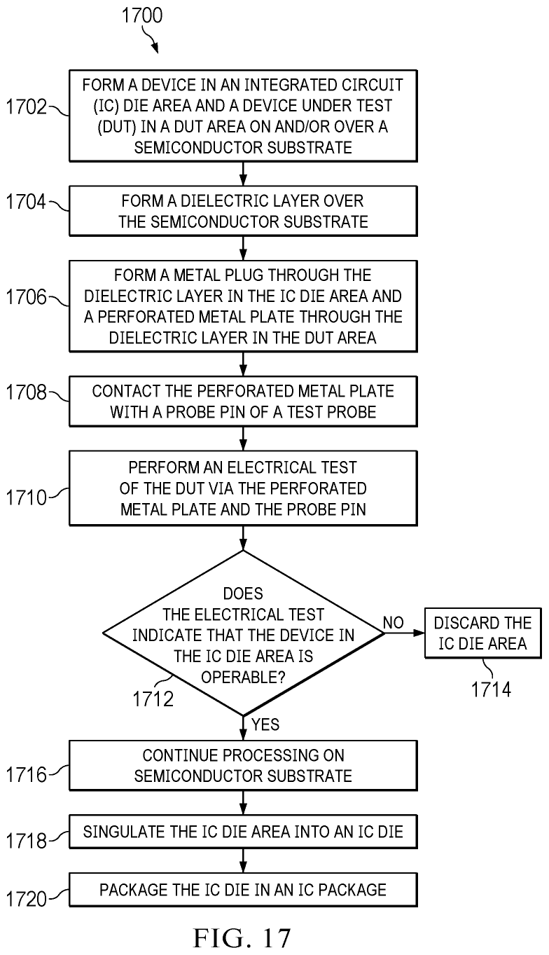

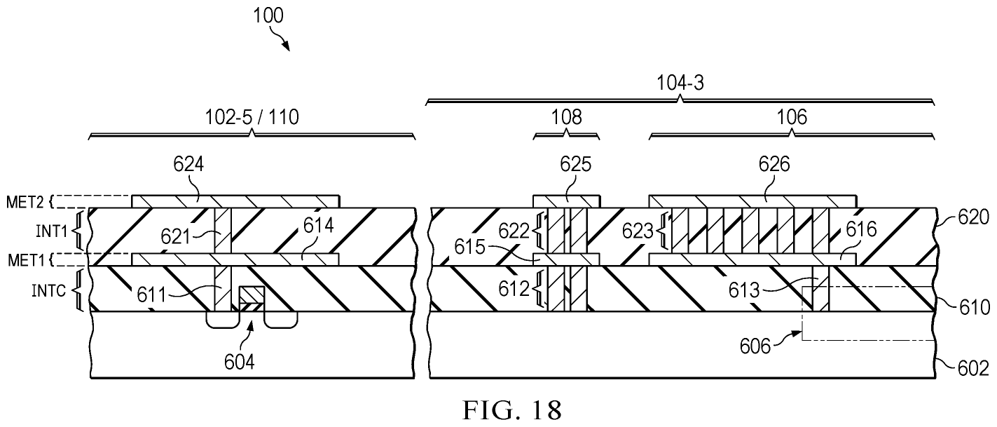

FIG. 17 is a flow chart of a method 1700 of semiconductor processing according to some examples, and FIGS. 18 through 22 are cross-sectional views during the method 1700 of semiconductor processing to form the substrate 100 of FIG. 6. As stated previously, the conductive perforated plate 502 is formed in the INT2 of the substrate 100 of FIG. 6, and the method 1700 in the context of FIGS. 18 through 22 is described as such. In other examples, the conductive perforated plate 502 is formed in another INT (e.g., INTC, INT1, . . . INT5, INTP), and the method 1700 may be implemented with the conductive perforated plate 502 being formed in such other INT. Further, the method 1700 may be implemented to form the substrate 200, 300 of FIG. 2 or 3, which includes a conductive perforated plate at any INT.

At block 1702, a device in an IC die area and a DUT in a DUT area are formed on and/or over a semiconductor substrate. Referring to FIG. 18, using any appropriate front-end-of-the-line (FEOL) processing, the device 604 is formed in the device cell area 110 of the IC die area 102-5, and the DUT 606 is formed in the DUT area 106. The DUT 606 is formed in the DUT area 106 adjacent to the IC die area 102-5 in which the device 604 is formed.

Referring back to FIG. 17, at block 1704, a dielectric layer is formed over the semiconductor substrate. At block 1706, a metal plug (e.g., a metal contact or metal via) is formed through the dielectric layer in the IC die area and a conductive perforated plate is formed through the dielectric layer in the DUT area. Various processing may be performed between blocks 1702 and 1704.

Referring to FIG. 18, as an example, the PMD layer 610, INTC, MET1, ILD1 layer 620, INT1, and MET2 are formed between blocks 1702 and 1704 in the method 1700 of FIG. 17. Generally, one or more dielectric layers of the PMD layer 610 is deposited using an appropriate deposition process, such as plasma enhanced chemical vapor deposition (PECVD), atomic layer deposition (ALD), the like, or a combination thereof. The PMD layer 610 may thereafter be planarized to have a planar top surface, such as by a chemical mechanical polish (CMP). The metal contacts 611, 612, 613 of the INTC may be formed by forming openings through the PMD layer 610 using appropriate photolithography and etching techniques, depositing metal into the openings, and removing any excess metal from the top surface of the PMD layer 610. The metal may be deposited using ALD, chemical vapor deposition (CVD), physical vapor deposition (PVD), the like, or a combination thereof. Any excess metal may be removed using CMP. Then, the metal line/pad 614, metal line 615, and metal pad 616 of the MET1 may be formed by depositing metal onto the top surface of the PMD layer 610 and patterning the metal into the metal line/pad 614, metal line 615, and metal pad 616. The metal may be deposited by PVD, CVD, the like, or a combination thereof, and may be patterned using appropriate photolithography and etching techniques.

Then, one or more dielectric layers of the ILD1 layer 620 is deposited using an appropriate deposition process, such as PECVD, ALD, the like, or a combination thereof. The ILD1 layer 620 may thereafter be planarized to have a planar top surface, such as by CMP. The metal vias 621, 622, 623 of the INT1 may be formed by forming openings through the ILD1 layer 620 using appropriate photolithography and etching techniques, depositing metal into the openings, and removing any excess metal from the top surface of the ILD1 layer 620. The metal may be deposited using ALD, CVD, PVD, the like, or a combination thereof. Any excess metal may be removed using CMP. Then, the metal line/pad 624, metal line 625, and metal pad 626 of the MET2 may be formed by depositing metal onto the top surface of the ILD1 layer 620 and patterning the metal into the metal line/pad 624, metal line 625, and metal pad 626. The metal may be deposited by PVD, CVD, the like, or a combination thereof, and may be patterned using appropriate photolithography and etching techniques.

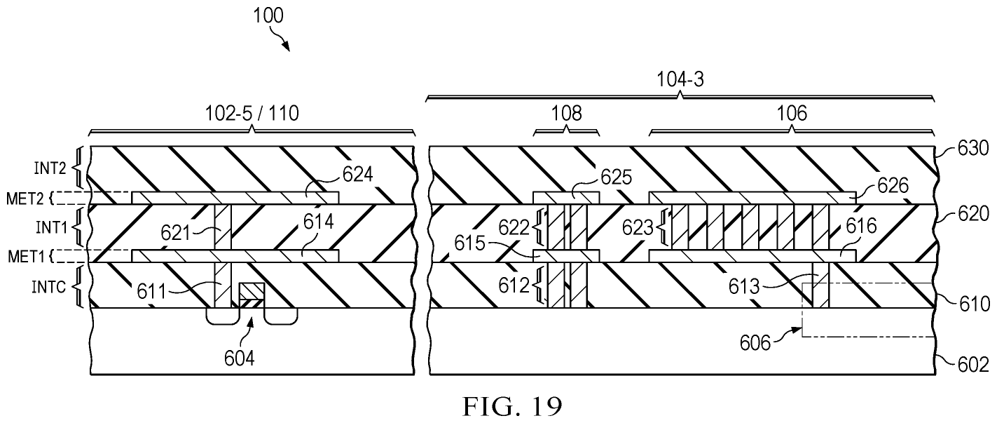

Referring to FIG. 19 and block 1704 of FIG. 17, the ILD2 layer 630 is formed over the semiconductor substrate 602 (e.g., over the ILD1 layer 620 and MET2). One or more dielectric layers of the ILD2 layer 630 is deposited using an appropriate deposition process, such as PECVD, ALD, the like, or a combination thereof. The ILD2 layer 630 may thereafter be planarized to have a planar top surface, such as by CMP.

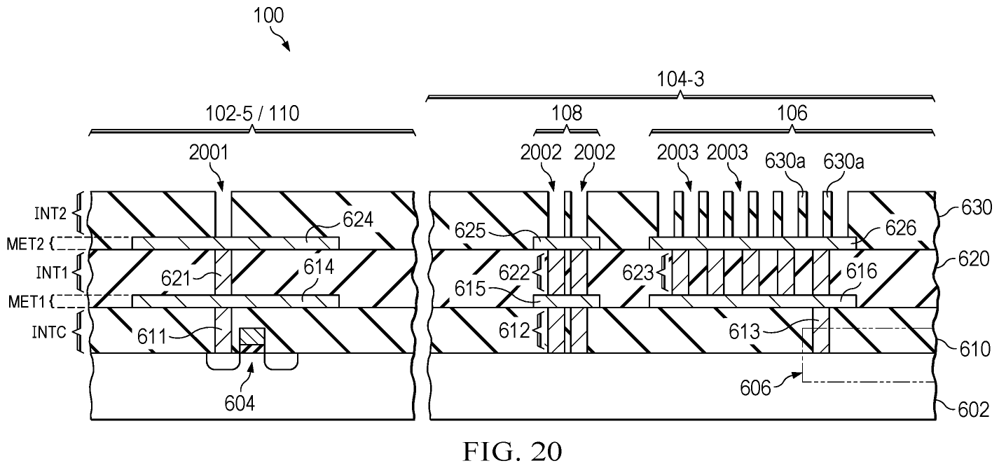

Referring to FIG. 20 and block 1706 of FIG. 17, to form a metal via 631 and conductive perforated plate 502 through the ILD2 layer 630, openings 2001, 2003 are formed through the ILD2 layer 630. Additionally, to form metal vias 632, openings 2002 are formed through the ILD2 layer 630. The opening 2001 through the ILD2 layer 630 exposes the metal line/pad 624 of the MET2. The openings 2002 through the ILD2 layer 630 expose the metal line 625 of the MET2. The opening 2003 through the ILD2 layer 630 exposes the metal pad 626 of the MET2. The insulating islands 630a are formed from the ILD2 layer 630 by the formation of the opening 2003. The openings 2001, 2002, 2003 may be formed by using appropriate photolithography and etching techniques.

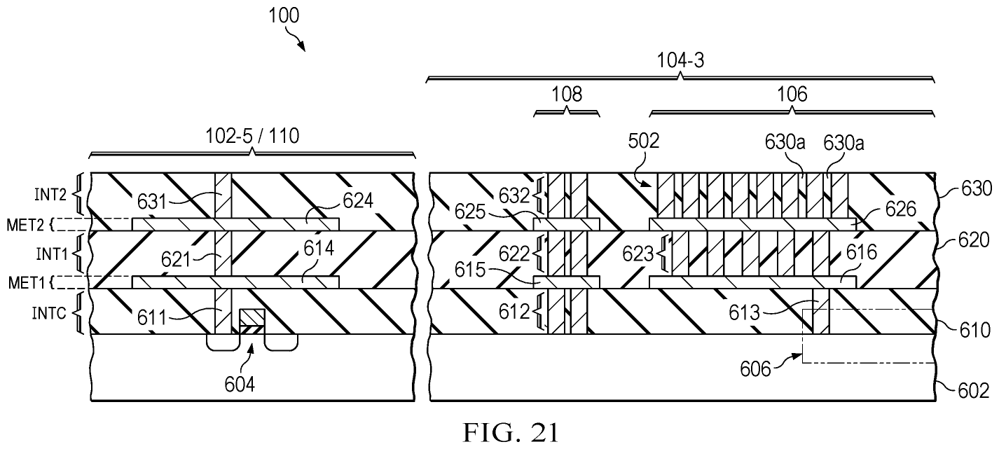

Referring to FIG. 21 and block 1706 of FIG. 17, the metal via 631 is formed through the ILD2 layer 630 in device cell area 110 of the IC die area 102-5, and the conductive perforated plate 502 is formed through the ILD2 layer 630 in the DUT area 106. Additionally, the metal vias 632 are formed through the ILD2 layer 630 in the scribe seal 108 in the scribe lane 104-3. The metal vias 631, 632 and conductive perforated plate 502 of the INT2 may be formed by depositing metal into the openings 2001, 2002, 2003 and removing any excess metal from the top surface of the ILD2 layer 630. The metal may be deposited using ALD, CVD, PVD, the like, or a combination thereof. Any excess metal may be removed using CMP.

Referring to FIG. 17, at block 1708, the conductive perforated plate is contacted with a probe pin of a test probe, and at block 1710, an electrical test of the DUT is performed via the conductive perforated plate and the probe pin. The contacting of the conductive perforated plate 502 and the performance of the electrical test of the DUT 606 may be as described above with respect to FIG. 11.

Referring to FIG. 17, at block 1712, a determination of whether the electrical test indicates that the device in the IC die area is operable is made. Results from an electrical test may differ based on the type of DUT, and interpretation of such results may be dependent upon the type of DUT, for example. If the electrical test indicates that the device is not operable, at block 1714, the IC die area is discarded. Otherwise, at block 1716, processing on the semiconductor substrate continues. In some instances, multiple DUTs across a substrate may be tested, in which some DUTs fail the test while others pass. IC die areas corresponding with failed DUTs may be tagged for subsequent discarding after subsequent processing of the substrate to fabricate IC die areas that corresponding to passing DUTs, for example. In some instances, a substrate may be discarded when a sufficient number of DUTs fail the electrical test.

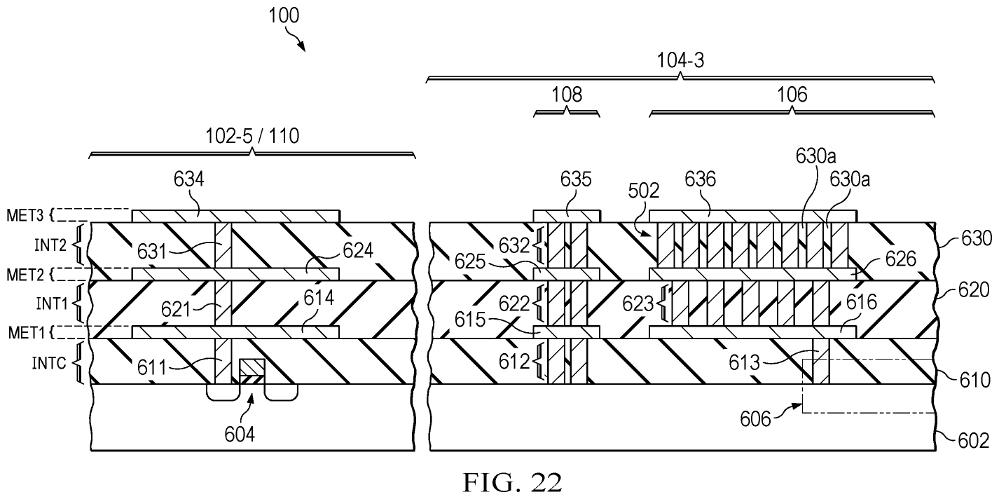

Referring to FIG. 22 and block 1716 of FIG. 17, continued processing includes forming the metal line/pad 634, metal line 635, and metal pad 636 of the MET2. The metal line/pad 634, metal line 635, and metal pad 636 may be formed by depositing metal onto the top surface of the ILD2 layer 630 and patterning the metal into the metal line/pad 634, metal line 635, and metal pad 636. The metal may be deposited by PVD, CVD, the like, or a combination thereof, and may be patterned using appropriate photolithography and etching techniques. Additionally, subsequently, the ILD3 layer 640, ILD4 layer 650, and ILD5 layer 660 may be formed similarly to the formation of the ILD2 layer 630. The INT3, INT4, INT5, and where applicable, INTP, may be formed similarly to the formation of the INT2. The MET4, MET5 and MET6 may be formed similarly to the formation of the MET3. The passivation dielectric layer 670 may be formed by an appropriate deposition process, such as CVD, and patterned to expose the metal line/pads 664, 402 by appropriate photolithography and etching techniques.

Although not described, additional electrical tests may be performed throughout processing. For example, an electrical test may be performed after formation of the passivation dielectric layer 670 by contacting a probe pin of a test probe to the metal line/pad 402. Further, other electrical tests may be performed on other conductive perforated plates in other INTs. Additionally, a conductive perforated plate may be in a different INT, as illustrated by FIGS. 12, 13, and 14, which may result in differing subsequent processing at block 1716.

Referring back to FIG. 17, at block 1718, the IC die area is singulated into an IC die. The IC die may be singulated by sawing, dicing, laser cutting, or the like. FIGS. 15A and 15B illustrate an IC die 1500 that is singulated. At block 1720 of FIG. 17, the IC die is packaged in an IC package. For example, the IC die may be attached to a leadframe, and a wire may be bonded between a metal pad of the IC die and a lead. The IC die and leadframe may then be encapsulated by an encapsulant, such as a molding compound. FIG. 16 illustrates the IC die 1500 packaged in the IC package 1600, as an example. Other IC packages, as described above, may be implemented.

Generally, at block 1720, the IC die is packaged on the condition that the electrical test performed at block 1710 yields an acceptable result (e.g., that the electrical test indicates that the device in the IC die area is operable). It is to be understood that the condition may further include that any other applicable tests (e.g., electrical or otherwise) that may be performed on the DUT and/or device in the IC die area yields respective acceptable results.

Although various examples have been described in detail, it should be understood that various changes, substitutions, and alterations may be made therein without departing from the scope defined by the appended claims.

What is claimed is:

1. A method of forming a semiconductor device, the method comprising:
forming a device circuit in a die area in or over a semiconductor substrate, the device circuit having an interconnect level;
forming a device under test (DUT) in or over the semiconductor substrate; and
forming a conductive perforated plate in the interconnect level conductively connected to the DUT, a plurality of insulating islands being disposed within the conductive perforated plate.

2. The method of claim 1, wherein the conductive perforated plate comprises tungsten.

3. The method of claim 1, wherein the insulating islands form a hexagonal array.

4. The method of claim 1, wherein the DUT extends through and beyond a scribe lane.

5. The method of claim 1, wherein a pre-metal dielectric (PMD) layer is located between the conductive perforated plate and the semiconductor substrate.

6. The method of claim 1, wherein the conductive perforated plate is formed over and contacting a top-most metal level over the semiconductor substrate.

7. The method of claim 1, wherein the conductive perforated plate contacts a metal pad having a perimeter that circumscribes the conductive perforated plate.

8. The method of claim 1, wherein the plurality of insulating islands are arranged in an array within the conductive perforated plate.

9. The method of claim 1, further comprising forming a scribe seal between the conductive perforated plate and the die area.

10. The method of claim 1 further comprising:
contacting the conductive perforated plate with a probe pin of a test probe; and
performing an electrical test of the DUT using the conductive perforated plate and the probe pin.

11. A method of fabricating an integrated circuit, the method comprising:
contacting a perforated metal plate with a probe pin of a test probe, the perforated metal plate being conductively connected to a device under test formed on or over a semiconductor substrate and adjacent a die area of the semiconductor substrate, a plurality of insulating islands being disposed through the perforated metal plate;
performing an electrical test of the device under test with the probe pin in contact with the perforated metal plate; and
packaging a die comprising the die area.

12. An integrated circuit, comprising:
a device circuit in a die area in or over a semiconductor substrate, the device circuit having an interconnect level including a dielectric material over the semiconductor substrate;
a conductive plate in the interconnect level; and
a plurality of insulating islands within the conductive plate, the insulating islands including the dielectric material.

13. The integrated circuit of claim 12, wherein the conductive plate is conductively connected to a device under test disposed on or over the semiconductor substrate.

14. The integrated circuit of claim 12, wherein the conductive plate comprises tungsten.

15. The integrated circuit of claim 12, wherein the plurality of insulating islands within the conductive plate are arranged in a hexagonal array.

16. The integrated circuit of claim 12, wherein a pre-metal dielectric (PMD) layer is disposed between the conductive plate and the semiconductor substrate.

17. The integrated circuit of claim 12, wherein the dielectric material is disposed over a top-most metal level over the semiconductor substrate.

18. The integrated circuit of claim 12, wherein the conductive plate contacts a metal pad in a metal level, the metal pad having a perimeter that circumscribes a perimeter of the conductive plate.

19. The integrated circuit of claim 12, wherein the conductive plate is disposed in a remnant scribe lane.

20. The integrated circuit of claim 12, further comprising a scribe seal disposed between the conductive plate and the die area.
